(19) United States
(12) Patent Application Publication
(10) Pub. No.: US 2025/0372539 A1
(43) Pub. Date: Dec. 4, 2025

(54) SEMICONDUCTOR WAFER STRUCTURE AND SEMICONDUCTOR DEVICE

(71) Applicant: Novatek Microelectronics Corp., Hsinchu (TW)

(72) Inventors: Chun Han Chien, Hsinchu City (TW); Ying-Chung Lee, Hsinchu City (TW); Jyunyi Jhong, Hsinchu County (TW); Chien-Chen Ko, Hsinchu City (TW)

(73) Assignee: Novatek Microelectronics Corp., Hsinchu (TW)

(21) Appl. No.: 19/227,523

(22) Filed: Jun. 4, 2025

Related U.S. Application Data
(60) Provisional application No. 63/656,062, filed on Jun. 4, 2024.

(51) Int. Cl. H01L 23/00

(52) U.S. Cl. CPC H01L 23/562

(57) ABSTRACT

A semiconductor wafer structure includes a semiconductor wafer and a plurality of ditch sets. The semiconductor wafer has a plurality of die regions and a plurality of dicing streets disposed between the die regions for separating the plurality of die regions. The plurality of ditch sets are disposed between the plurality of die regions and plurality of dicing streets. Each of the plurality of die regions is surrounded by one of the plurality of ditch set, each of the plurality of ditch sets comprises a plurality of stress relief ditches parallel to one another.

### CROSS-REFERENCE TO RELATED APPLICATION

This application claims the priority benefit of U.S. provisional application Ser. No. 63/656,062, filed on Jun. 4, 2024. The entirety of the above-mentioned patent application is hereby incorporated by reference herein and made a part of this specification.

### BACKGROUND

### Technical Field

The present disclosure generally relates to a semiconductor wafer structure and a semiconductor device.

### Description of Related Art

In semiconductor wafer processing, integrated circuits are formed on a wafer (also referred to as a substrate) composed of silicon or other semiconductor material. In general, layers of various materials which are either semiconducting, conducting or insulating are utilized to form the integrated circuits. These materials are doped, deposited and etched using various well-known processes to form integrated circuits. Each wafer is processed to form a large number of individual regions containing integrated circuits known as dice or dies.

Following the integrated circuit formation process, the wafer is “diced” to separate the individual die from one another for packaging or for use in an unpackaged form within larger circuits. For dicing process, the wafer is usually mounted on a supporting member such as an adhesive film stretched across a film frame and the saw is repeatedly applied to both the vertical and horizontal streets. One problem with either scribing or sawing is that chips and gouges can form along the severed edges of the dies. In addition, cracks can form and propagate from the edges of the dies into the substrate and render the integrated circuit inoperative. Because of chipping and cracking, additional spacing is often required between the dies on the wafer to prevent damage to the integrated circuits. Such additional spacing can keep the chips and cracks at a distance from the actual integrated circuits. As a result of the spacing requirements, not as many dies can be formed on a standard sized wafer and wafer real estate that could otherwise be used for circuitry is wasted.

### SUMMARY

Accordingly, the present disclosure is directed to a semiconductor wafer structure and a semiconductor device having stress relief ditches surrounding a die region to release the stress caused by dicing process.

The disclosure provides a semiconductor wafer structure includes a semiconductor wafer and a plurality of ditch sets. The semiconductor wafer has a plurality of die regions and a plurality of dicing streets disposed between the die regions for separating the plurality of die regions. The plurality of ditch sets are disposed between the plurality of die regions and plurality of dicing streets. Each of the plurality of die regions is surrounded by one of the plurality of ditch set, each of the plurality of ditch sets comprises a plurality of stress relief ditches parallel to one another.

According to an embodiment of the present disclosure, wherein the semiconductor wafer further comprising a semiconductor substrate, a redistribution structure formed over the semiconductor substrate, and a passivation layer covering the redistribution structure and the plurality of dicing streets.

According to an embodiment of the present disclosure, wherein each of the plurality of stress relief ditches is extended at least through the passivation layer.

According to an embodiment of the present disclosure, wherein each of the plurality of ditch set comprises at least 3 stress relief ditches, and each of the at least 3 stress relief ditches enclosing a respective one of the plurality of die regions.

According to an embodiment of the present disclosure, wherein the semiconductor wafer further comprises a dicing region to be removed during a dicing process, and the dicing region overlaps with the plurality of dicing streets.

According to an embodiment of the present disclosure, wherein the dicing region partially overlaps with each of the plurality of ditch sets.

According to an embodiment of the present disclosure, wherein a width of the dicing region is greater than a width of each of the plurality of dicing streets.

According to an embodiment of the present disclosure, wherein a width of each of the plurality of dicing streets is substantially equal to or smaller than 50 μm.

According to an embodiment of the present disclosure, wherein a gap between adjacent two of the plurality of stress relief ditches is substantially equal to or smaller than 4 μm.

According to an embodiment of the present disclosure, wherein a width of each of the plurality of stress relief ditches is substantially equal to or smaller than 4 μm.

The disclosure provides a semiconductor device including a semiconductor substrate having a die region and an edge region outside a periphery of the die region and surrounding the die region, and a plurality of stress relief ditches disposed within the edge region and surrounding the die region. The plurality of stress relief ditches parallel to one another.

According to an embodiment of the present disclosure, wherein the plurality of stress relief ditches comprises at least one first ditch surrounding the die region and a second ditch surrounding the at least one first ditch and the die region.

According to an embodiment of the present disclosure, wherein a width of the second ditch is smaller than a width of the at least one first ditch.

According to an embodiment of the present disclosure, wherein a bottom surface of the second ditch is extended to and connecting an outermost side surface of the semiconductor device.

According to an embodiment of the present disclosure, the semiconductor device further includes a redistribution structure disposed over the semiconductor substrate, and a passivation layer disposed over the redistribution structure and the edge region.

According to an embodiment of the present disclosure, each of the plurality of stress relief ditches is extended at least through the passivation layer.

According to an embodiment of the present disclosure, wherein a gap between adjacent two of the plurality of stress relief ditches is substantially equal to or smaller than 4 μm.

According to an embodiment of the present disclosure, wherein a width of each of the plurality of stress relief ditches is substantially equal to or smaller than 4 μm.

The disclosure provides a semiconductor device including a semiconductor substrate having a die region and an edge region outside a periphery of the die region and surrounding the die region, and a stress relief ditch disposed within the edge region and surrounding the die region. A bottom surface of the stress relief ditch is extended to and connecting an outermost side surface of the semiconductor device.

According to an embodiment of the present disclosure, the semiconductor device further includes at least one ditch surrounding the die region and surrounded by the stress relief ditch, wherein a width of the stress relief ditch is smaller than a width of the at least one ditch.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a partial top view of a semiconductor wafer structure according to some exemplary embodiments in the present disclosure.

FIG. 2 is a partial cross-sectional view of a semiconductor wafer structure according to some exemplary embodiments in the present disclosure.

FIG. 3 is a cross-sectional view of a semiconductor device according to some exemplary embodiments in the present disclosure.

FIG. 4 is a partial enlarged view of an edge region of the semiconductor device in FIG. 3.

FIG. 5 to FIG. 7 are cross-sectional views of semiconductor devices according to different exemplary embodiments in the present disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

Reference will now be made in detail to the present preferred embodiments of the disclosure, examples of which are illustrated in the accompanying drawings. Wherever possible, the same reference numbers are used in the drawings and the description to refer to the same or like parts. The terms used herein such as “on”, “above”, “below”, “front”, “back”, “left” and “right” are for the purpose of describing directions in the figures only and are not intended to be limiting of the disclosure. Further, in the discussion and claims herein, the term “on” used with respect to two materials, one “on” the other, means at least some contact between the materials, while “over” and “overlie” mean the materials are in proximity, but possibly with one or more additional intervening materials such that physical contact is possible but not required. Neither “on” nor “over” implies any directionality as used herein.

Unless limited otherwise, the terms “disposed”, “connected”, “coupled”, “mounted” and variations thereof herein are used broadly and encompass direct and indirect connections, couplings, and mountings. Similarly, the terms “facing”, “faces” and variations thereof herein are used broadly and encompass direct and indirect facing, and “adjacent to” and variations thereof herein are used broadly and encompass directly and indirectly “adjacent to”. Accordingly, the drawings and descriptions will be regarded as illustrative in nature and not as restrictive.

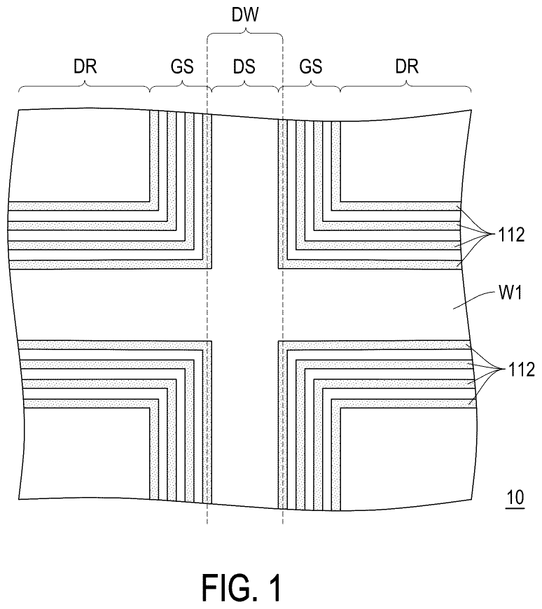

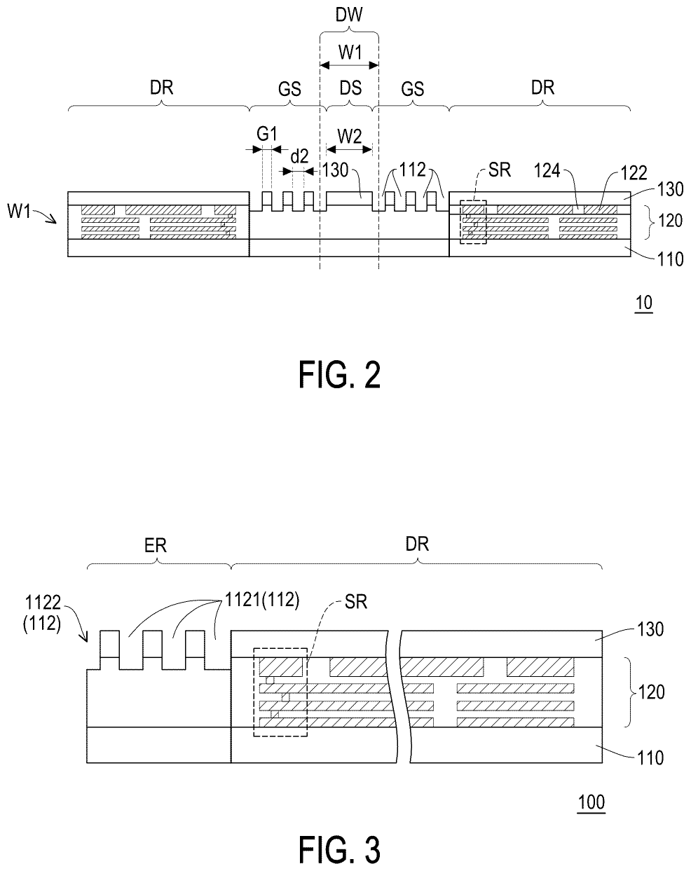

FIG. 1 is a partial top view of a semiconductor wafer structure according to some exemplary embodiments in the present disclosure. FIG. 2 is a partial cross-sectional view of a semiconductor wafer structure according to some exemplary embodiments in the present disclosure. Referring to FIG. 1 and FIG. 2, a semiconductor wafer structure 10 includes a semiconductor wafer W1 and a plurality of ditch sets GS formed over the semiconductor wafer W1 for surrounding each of die regions (dies) DR on the semiconductor wafer W1. In some embodiments, the semiconductor wafer W1 includes a plurality of die regions DR, a plurality of dicing streets DS disposed between the die regions DR for separating the die regions DR. The dicing streets DS are configured to permit passage of a dicing saw with a reduced risk of damage to adjacent die regions DR on the semiconductor wafer W1. In one embodiment, the dicing streets DS may include features such as test pads to test performance of the die regions DR formed during the manufacturing process, alignment marks for assisting with alignment of various masks during the manufacturing process, and/or other identifying information.

In some embodiments, the semiconductor wafer W1 includes a semiconductor substrate 110 for supporting the die regions (dies) DR formed thereon. In some embodiments, devices of the dies extend into the semiconductor substrate 110. In some embodiments, the semiconductor substrate 110 includes an elementary semiconductor including silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof.

In accordance to some exemplary embodiments in the present disclosure, each of the die regions DR may have the same function. In some embodiments, at least one of the die regions DR has a different function from another one of the die regions DR. In some embodiments, each of the die regions DR has a same size. In some embodiments, at least one of the die regions DR has a different size from another one of the die regions DR.

In some embodiments, the die regions DR are formed over the semiconductor substrate 110. The die regions DR are formed through a combination of manufacturing processes, such as photolithography, deposition, etching, epitaxy, implantation or other suitable processes. In some embodiments, each of the die regions DR may include planar devices, such as complementary metal-oxide-semiconductor (CMOS) devices, high electron mobility transistors (HEMTs), bi-polar junction transistors (BJTs) or other suitable planar devices. In some embodiments, each of the die regions DR includes passive components, such as capacitors, resistors, inductors or other suitable passive components. In some embodiments, each of the die regions DR includes a combination of passive devices and active devices, such as transistors or other suitable active devices.

The die regions DR are separated by the dicing streets DS, which may include metallization and dielectric layers similar to those of the die regions DR. For example, the dicing streets DS may be composed of layers of dielectric materials, semiconductor materials, and metallization. In one embodiment, one or more of the dicing streets DS includes test devices similar to the actual devices of the die regions DR. In some embodiments, backside metallization layers (and corresponding dielectric layers) may be included on the backside of the semiconductor wafer W1 or semiconductor substrate 110.

In accordance with some embodiments of the present disclosure, the semiconductor wafer W1 further includes a redistribution structure 120 formed over the semiconductor substrate 110, and a passivation layer 130 covering the redistribution structure 120 and the plurality of dicing streets DS. In some embodiments, the redistribution structure 120 may include a plurality of redistribution layers (RDLs) 122 and a plurality of dielectric layers 124 stacked over one another. Each of the dielectric layers 124 may be formed of a polymer such as PBO, polyimide, or the like. The formation process includes coating dielectric layer 124 in a flowable form, and then curing dielectric layer 124. In accordance with alternative embodiments of the present disclosure, dielectric layer 124 is formed of an inorganic dielectric material such as silicon nitride, silicon oxide, or the like. The formation method may include Chemical Vapor Deposition (CVD), Atomic Layer Deposition (ALD), Plasma-Enhanced Chemical Vapor Deposition (PECVD), or other applicable deposition methods. Openings (occupied by the via portions of RDLs 122) are then formed, for example, through a photo lithography process. In accordance with some embodiments in which the dielectric layer 124 is formed of a photo sensitive material such as PBO, polyimide, or benzocyclobutene (BCB), the formation of the openings involves a photo exposure of dielectric layer 124 using a lithography mask (not shown), and developing the dielectric layer 124.

The RDLs 122 may be formed over the corresponding dielectric layers 124 respectively. In some embodiments, the RDLs 122 include via portions formed in dielectric layers 124 for interconnection. In accordance with some embodiments of the present disclosure, the RDLs 122 are formed in a plating process, which includes depositing a metal seed layer (not shown), forming and patterning a photo resist (not shown) over the metal seed layer, and plating a metallic material such as copper and/or aluminum over the metal seed layer. The metal seed layer and the plated metallic material may be formed of the same material or different materials. The patterned photo resist is then removed, followed by etching the portions of the metal seed layer previously covered by the patterned photo resist. The numbers of the RDLs 122 and the dielectric layers 124 illustrated in the present disclosure are merely for illustration purpose. The layout and the number of layers of the redistribution structure 120 are not limited thereto.

In some embodiments, each of the die regions DR may further include a seal ring SR extending around the periphery of the corresponding die region DR, as illustrated schematically in FIG. 2. The seal ring SR is formed over the inactive area which surrounds the active area of the die region DR. The seal ring structure SR helps to reduce crack propagating into active areas of the redistribution structure 120, and also helps to block electro-migration of contaminant ions.

After the redistribution structure 120 is formed, the passivation layer 130 is formed to comprehensively cover the upper surface of the semiconductor wafer W1 (including the redistribution structure 120 and the plurality of dicing streets DS). The passivation layer 130 may has the function of isolating the RDLs 122 and the (low-k) dielectric layers 124 from the adverse effect of detrimental chemicals and moisture. The passivation layer 130 may be formed of non-low-k dielectric materials such as silicon oxide, silicon nitride, Undoped Silicate Glass (USG), or the like. There may be metal pads such as aluminum pads (which may be formed of aluminum copper, for example) in the passivation layers.

In accordance to some exemplary embodiments in the present disclosure, the ditch sets GS are disposed between the die regions DR, and each of the die regions DR is surrounded by one of the ditch sets GS. In detail, each of the ditch sets GS includes a plurality of stress relief ditches 112 parallel to one another. For example, each of the ditch sets GS includes at least 3 stress relief ditches 112, and each of the stress relief ditches 112 enclosing a respective one of the die regions DR. In some embodiments, the stress relief ditches 112 may be formed by, for example, etching process, etc., for surrounding the periphery of each of the die regions DR. In one embodiments, each of the stress relief ditches 112 is etched to be extended at least through the passivation layer 130. The stress relief ditches 112 are formed prior to wafer dicing process and configured to separate the active area of each die region DR, and part of the surrounding inactive area (edge region), from the dicing street DS.

Referring to FIG. 2, in some embodiments, the semiconductor wafer W1 further includes a dicing region DW that is to be removed during a dicing process, and the dicing region DW overlaps with the dicing streets DS. The dicing streets DS are configured for separating multiple die regions DR fabricated on the semiconductor substrate 110. The dicing streets DS may include alignment marks for dicing as well as other structures such as test and monitoring structures. The dicing region DW is the region that is actually removed by a dicing tool such as a blade saw, during the dicing process. A width W1 of the dicing region DW is substantially equal to a width of the dicing tool. In some embodiments, the dicing region DW overlapping the dicing streets DS from a top view means the width W1 of the dicing region DW is substantially greater than the width W2 of each of the dicing streets DS. For example, the width W1 of the dicing region DW is greater than about 50 μm, and the width W2 of each of the dicing streets DS is substantially equal to or smaller than about 50 μm.

Accordingly, the dicing region DW may partially overlap with each of the ditch sets GS since the ditch sets GS are configured to be right adjacent to the dicing streets DS. That is, a part of the ditch sets GS may be removed during the dicing process. With such arrangement, as illustrated schematically in FIG. 2 and FIG. 3, after the dicing process, any stress concentration caused by the dicing process can be released by the stress relief ditches 112 right at the beginning, and any dicing induced defects or cracks can be blocked by the stress relief ditches 112 from propagation or migration into the active area of the die regions DR. In some embodiments, a gap G1 between adjacent two of the stress relief ditches 112 is substantially equal to or smaller than 4 μm, and a width d2 of each of the stress relief ditches 112 is substantially equal to or smaller than 4 μm. An aspect ratio of each of the stress relief ditches 112 may be about 3:1 or about 4:1. The disclosure is not limited thereto. In addition, the stress relief ditches 112 divide the semiconductor wafer structure 10 into multiple smaller regions (by surrounding each of the die regions DR), so that the total integrated tensile stress across the wafer is relieved.

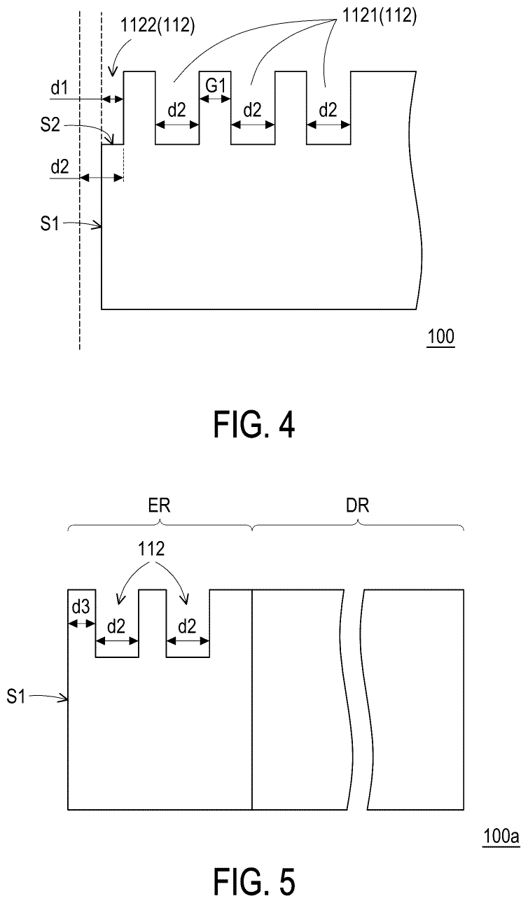

FIG. 3 is a cross-sectional view of a semiconductor device according to some exemplary embodiments in the present disclosure. FIG. 4 is a partial enlarged view of an edge region of the semiconductor device in FIG. 3. It is noted that the semiconductor device 100 shown in FIG. 3 and FIG. 4 is one of the dies diced from the semiconductor wafer structure 10 shown in FIG. 1 and FIG. 2. Accordingly, the semiconductor device 100 shown in FIG. 3 and FIG. 4 contains many features same as or similar to the semiconductor wafer structure 10 disclosed earlier with FIG. 1 and FIG. 2. For purpose of clarity and simplicity, detail description of same or similar features may be omitted, and the same or similar reference numbers denote the same or like components.

Referring to FIG. 3 and FIG. 4, in some embodiments, the semiconductor device 100 includes a semiconductor substrate 110 and a plurality of stress relief ditches 112. The semiconductor substrate 110 has a die region DR and an edge region ER outside a periphery of the die region DR, and the edge region ER surrounds the die region DR. In some embodiments, the semiconductor device 100 further includes a redistribution structure 120 disposed over the semiconductor substrate 110, and a passivation layer 130 disposed over the redistribution structure 120 and the edge region ER. The stress relief ditches 112 are disposed within the edge region ER and surround the die region DR. In some embodiments, the stress relief ditches 112 are parallel to one another and extended at least through the passivation layer 130. In one embodiment, a gap G1 between adjacent two of the stress relief ditches 112 is substantially equal to or smaller than about 4 μm.

In the present embodiment, at least a part of the stress relief ditches 112 is removed by the dicing tool during the dicing process. Accordingly, the stress relief ditches 112 includes at least one first ditch 1121 (3 first ditches 1121 are illustrated herein, but not limited thereto) surrounding the die region DR and a second ditch 1122 surrounding the first ditch 1121 and the die region DR. For example, a width d2 of each of the first ditch 1121 is substantially equal to or smaller than about 4 μm, and a width d1 of the second ditch 1122 is smaller than a width d2 of the first ditch 1121 since the second ditch 1122 is the one of the stress relief ditches 112 got partially removed by the dicing tool. As such, a bottom surface S2 of the second ditch 1122 is extended to and connecting an outermost side surface S1 of the semiconductor device 100.

FIG. 5 is cross-sectional view of a semiconductor device according to some exemplary embodiments in the present disclosure. It is noted that the semiconductor device 100a shown in FIG. 5 contains many features same as or similar to the semiconductor device disclosed in the previous embodiments. For purpose of clarity and simplicity, detail description of same or similar features may be omitted, and the same or similar reference numbers denote the same or like components.

Referring to FIG. 5, in the present embodiment, the dicing tool does not dice off any one of the stress relief ditches 112 or the dicing tool dices at the region between two adjacent stress relief ditches 112. That is, there is no stress relief ditches 112 that is partially removed by the dicing tool during the dicing process. Accordingly, the semiconductor device 100a includes at least one stress relief ditch 112 (two stress relief ditches 112 are illustrated herein, but not limited thereto) disposed within the edge region ER and surrounding the die region DR, and the widths d2 of the stress relief ditches 112 are substantially the same. As such, the outermost side surface S1 of the semiconductor device 100a is a planar surface and a horizontal distance d3 from the outermost side surface S1 to the closest sidewall of the stress relief ditches 112 is substantially smaller than about 4 μm. For example, the horizontal distance d3 is substantially equal to or smaller than about 2 μm. The disclosure is not limited thereto.

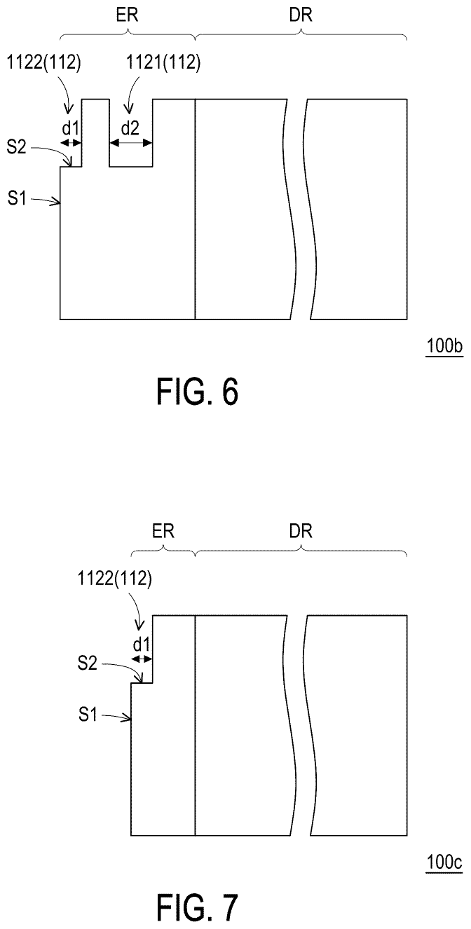

FIG. 6 is cross-sectional view of a semiconductor device according to some exemplary embodiments in the present disclosure. It is noted that the semiconductor device 100b shown in FIG. 6 contains many features same as or similar to the semiconductor device disclosed in the previous embodiments. For purpose of clarity and simplicity, detail description of same or similar features may be omitted, and the same or similar reference numbers denote the same or like components.

Referring to FIG. 6, in the present embodiment, the stress relief ditches 112 includes a first ditch 1121 surrounding the die region DR and a second ditch 1122 surrounding the first ditch 1121, and a part of the second ditch 1122 is removed by the dicing tool during the dicing process. Accordingly, a width d1 of the second ditch 1122 is smaller than a width d2 of the first ditch 1121 since the second ditch 1122 is the one of the stress relief ditches 112 got partially removed by the dicing tool. As such, a bottom surface S2 of the second ditch 1122 is extended to and connecting an outermost side surface S1 of the semiconductor device 100b.

FIG. 7 is cross-sectional view of a semiconductor device according to some exemplary embodiments in the present disclosure. It is noted that the semiconductor device 100c shown in FIG. 7 contains many features same as or similar to the semiconductor device disclosed in the previous embodiments. For purpose of clarity and simplicity, detail description of same or similar features may be omitted, and the same or similar reference numbers denote the same or like components.

Referring to FIG. 7, in the present embodiment, the dicing tool dices at one of the stress relief ditches 112 on the semiconductor wafer that is closest to the die region DR. Accordingly, the semiconductor device 100c includes a stress relief ditch 1122 disposed within the edge region ER and surrounding the die region DR, and the stress relief ditch 1122 is partially removed by the dicing tool. As such, a bottom surface S2 of the stress relief ditch 1122 is extended to and connecting an outermost side surface S1 of the semiconductor device 100c. In some embodiments, a width d1 of the stress relief ditch 1122 is smaller than about 4 μm. For example, a width d1 of the stress relief ditch 1122 is substantially equal to or smaller than about 2 μm.

In sum, the disclosure provides a semiconductor wafer structure having a plurality of stress relief ditches surrounding each of the die regions and disposed right adjacent to the dicing streets. Accordingly, a semiconductor device diced from the semiconductor wafer structure includes at least one stress relief ditch surrounding the die region. With such arrangement, after the dicing process, any stress concentration caused by the dicing process can be instantly released by the stress relief ditches before any crack dicing induced defects or cracks are formed. Even if some defects or cracks are formed, they can be blocked by the stress relief ditches right at the beginning to prevent them from propagation or migration into the active area of the die regions. Therefore, yield rate and reliability of the semiconductor device can be improved, and the edge region of the semiconductor wafer structure can be reduced, so as to optimize the space utilization of the semiconductor wafer structure.

Based on the above discussions, it can be seen that the present disclosure offers various advantages. It is understood, however, that not all advantages are necessarily discussed herein, and other embodiments may offer different advantages, and that no particular advantage is required for all embodiments.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor wafer structure, comprising:
a semiconductor wafer having a plurality of die regions, and a plurality of dicing streets disposed between the plurality of die regions for separating the plurality of die regions; and
a plurality of ditch sets disposed between the plurality of die regions, wherein each of the plurality of die regions is surrounded by one of the plurality of ditch sets, each of the plurality of ditch sets comprises a plurality of stress relief ditches parallel to one another.

2. The semiconductor wafer structure as claimed in claim 1, wherein the semiconductor wafer further comprising a semiconductor substrate, a redistribution structure formed over the semiconductor substrate, and a passivation layer covering the redistribution structure and the plurality of dicing streets.

3. The semiconductor wafer structure as claimed in claim 2, wherein each of the plurality of stress relief ditches is extended at least through the passivation layer.

4. The semiconductor wafer structure as claimed in claim 1, wherein each of the plurality of ditch set comprises at least 3 stress relief ditches, and each of the at least 3 stress relief ditches enclosing a respective one of the plurality of die regions.

5. The semiconductor wafer structure as claimed in claim 1, wherein the semiconductor wafer further comprises a dicing region to be removed during a dicing process, and the dicing region overlaps with the plurality of dicing streets.

6. The semiconductor wafer structure as claimed in claim 1, wherein the dicing region partially overlaps with each of the plurality of ditch sets.

7. The semiconductor wafer structure as claimed in claim 5, wherein a width of the dicing region is greater than a width of each of the plurality of dicing streets.

8. The semiconductor wafer structure as claimed in claim 1, wherein a width of each of the plurality of dicing streets is substantially equal to or smaller than 50 μm.

9. The semiconductor wafer structure as claimed in claim 1, wherein a gap between adjacent two of the plurality of stress relief ditches is substantially equal to or smaller than 4 μm.

10. The semiconductor wafer structure as claimed in claim 1, wherein a width of each of the plurality of stress relief ditches is substantially equal to or smaller than 4 μm.

11. A semiconductor device, comprising:
a semiconductor substrate having a die region and an edge region outside a periphery of the die region and surrounding the die region; and
a plurality of stress relief ditches disposed within the edge region and surrounding the die region, wherein the plurality of stress relief ditches parallel to one another.

12. The semiconductor device as claimed in claim 11, wherein the plurality of stress relief ditches comprises at least one first ditch surrounding the die region and a second ditch surrounding the at least one first ditch and the die region.

13. The semiconductor device as claimed in claim 12, wherein a width of the second ditch is smaller than a width of the at least one first ditch.

14. The semiconductor device as claimed in claim 12, wherein a bottom surface of the second ditch is extended to and connecting an outermost side surface of the semiconductor device.

15. The semiconductor device as claimed in claim 11, further comprising a redistribution structure disposed over the semiconductor substrate, and a passivation layer disposed over the redistribution structure and the edge region.

16. The semiconductor device as claimed in claim 15, wherein each of the plurality of stress relief ditches is extended at least through the passivation layer.

17. The semiconductor device as claimed in claim 11, wherein a gap between adjacent two of the plurality of stress relief ditches is substantially equal to or smaller than 4 μm.

18. The semiconductor device as claimed in claim 11, wherein a width of each of the plurality of stress relief ditches is substantially equal to or smaller than 4 μm.

19. A semiconductor device, comprising:
a semiconductor substrate having a die region and an edge region outside a periphery of the die region and surrounding the die region; and
a stress relief ditch disposed within the edge region and surrounding the die region, wherein a bottom surface of the stress relief ditch is extended to and connecting an outermost side surface of the semiconductor device.

20. The semiconductor device as claimed in claim 19, further comprising at least one ditch surrounding the die region and surrounded by the stress relief ditch, wherein a width of the stress relief ditch is smaller than a width of the at least one ditch.
